(19) United States
(12) Patent Application Publication
(10) Pub. No.: US 2019/0122890 A1
(43) Pub. Date: Apr. 25, 2019

(54) MULTIBATH PLATING OF A SINGLE METAL

(71) Applicant: Lam Research Corporation, Fremont, CA (US)

(72) Inventors: Kari Thorkelsson, Portland, OR (US); Nirmal Shankar, Sigamani, Sherwood, OR (US); Bryan L. Buckalew, Tualatin, OR (US); Steven T. Mayer, Aurora, OR (US); Thomas Anand Ponnuswamy, Sherwood, OR (US)

(21) Appl. No.: 16/165,886

(22) Filed: Oct. 19, 2018

Related U.S. Application Data
(60) Provisional application No. 62/574,426, filed on Oct. 19, 2017.

(51) Int. Cl. H01L 21/288; C25D 5/02; C25D 3/38; C25D 7/12; H01L 21/768; H01L 23/00; H01L 21/027

(52) U.S. Cl. CPC H01L 21/2885; C25D 5/022; C25D 3/38; C25D 7/12; H01L 21/76879; H01L 23/53228; H01L 21/0273; H01L 24/11; H01L 2224/11001; H01L 2224/11462; H01L 2224/13147; H01L 24/13

(57) ABSTRACT

A method of electroplating a metal into features of a partially fabricated electronic device on a substrate is provided. The method includes (a) electroplating the metal into the features, to partially fill the features by a bottom up fill mechanism, while contacting the features with a first electroplating bath having a first composition and comprising ions of the metal; (b) thereafter, electroplating more of the metal into the features, to further fill the features, while contacting the features with a second electroplating bath having a second composition, which is different than the first composition, and comprises the ions of the metal; and (c) removing the substrate from an electroplating tool where operation (b) was performed.

### CROSS-REFERENCE TO RELATED APPLICATIONS

This application claims benefit of U.S. Provisional Application No. 62/574,426, filed Oct. 19, 2017, and titled “MULTIBATH PLATING OF A SINGLE METAL,” which is incorporated herein by reference in its entirety and for all purposes.

### TECHNICAL FIELD

The present disclosure generally relates to electroplating for wafer-level packaging (WLP) applications. More particularly, it relates to a multi-bath electroplating approach to plate multiple layers of the same metal on features of a substrate to produce high feature uniformity at acceptable plating rates.

### BACKGROUND

Electrolyte solutions, e.g. metal plating baths, used in wafer-level-packaging applications typically are designed to produce acceptable within-die (WID), within-wafer (WIW) and within-feature (WIF) non-uniformity at acceptable deposition purity. Such non-uniformity is produced at acceptable electroplating rates by controlling the concentration of metal and acid in solution for the plating bath, as well as the selection of an additive package applied to the plating bath. However, more rapid electroplating rates often required for large pillar applications may result in substantial feature, or pillar, non-uniformity, or produce an impure deposit. Further technical challenges may arise while seeking to optimize plating bath chemistry to achieve ideal WID, WIW and WIF non-uniformity at acceptable electroplating rates and purities.

### SUMMARY

Provided herein are methods of electroplating a metal into features of a partially fabricated electronic device on a substrate. One aspect involves a method of (a) electroplating the metal into the features, to partially fill the features by a bottom up fill mechanism, while contacting the features with a first electroplating bath having a first composition and comprising ions of the metal; (b) thereafter, electroplating more of the metal into the features, to further fill the features, while contacting the features with a second electroplating bath having a second composition, which is different than the first composition, and comprises the ions of the metal; and (c) removing the substrate from an electroplating tool where operation (b) was performed.

In some embodiments, the metal is copper.

In some embodiments, the first electroplating bath and the second electroplating bath each comprise an acid.

In some embodiments, the first electroplating bath comprises only one type of dissolved anion.

In some embodiments, the first electroplating bath and the second electroplating bath each comprise copper sulfate and sulfuric acid.

In some embodiments, the first electroplating bath comprises two dissolved anions.

In some embodiments, the first electroplating bath comprises copper sulfate and methane sulfonic acid.

In some embodiments, the second electroplating bath comprises copper sulfate and sulfuric acid, but does not contain methane sulfonic acid.

In some embodiments, the first electroplating bath has a first concentration of the ions of the metal and the second electroplating bath has a second concentration of ions of the metal. Further, the first concentration may be greater than the second concentration. Moreover, in certain embodiments, the metal is copper and the first concentration of ions of copper is approximately 85 g/l, and wherein the second concentration of ions of copper is approximately 70 g/l. Alternatively, in other embodiments, the first concentration is lesser than the second concentration.

In some embodiments, the first electroplating bath has a first concentration of acid and the second electroplating bath has a second concentration of acid, and wherein the second concentration is greater than the first concentration. Alternatively, in other embodiments, the first concentration is lesser than the second concentration.

In some embodiments, the metal is copper and the first concentration of acid is approximately 145 g/l, and wherein the second concentration of acid is approximately 190 g/l.

In some embodiments, the first electroplating bath has a first additive composition and the second electroplating bath has a second additive composition, which is different from the first additive composition. Further, in certain embodiments, the first additive composition has stronger bottom-up fill properties compared to the second additive composition. Moreover, in some embodiments, the first additive composition may comprise a suppressor and an accelerator. Still further, in some embodiments, the first additive composition comprises a suppressor and an accelerator. The second additive composition may have stronger leveling properties compared to the first additive composition.

In some embodiments, the electroplating in (a) is performed at a first temperature, and wherein the electroplating in (b) is performed at a second temperature that is lower than the first temperature.

In some embodiments, the electroplating in (a) is performed at a first current density that is below a first limiting current density for electroplating metal in the feature during (a), and wherein the electroplating in (b) is performed at a second current density that is higher than first limiting current density, but lower than a second limiting current density for electroplating metal in the feature during (b).

In some embodiments, after (b), electroplating even more of the metal into the features, while contacting the features with a third electroplating bath having a third composition, which is different than the second composition, and comprises the ions of the metal.

In some embodiments, operation (a) is performed in a first electroplating chamber and operation (b) is performed in a second electroplating chamber. Further, in certain embodiments, the first electroplating chamber may be in a first electroplating tool having one or more stations and/or mechanisms shared by multiple electroplating chambers, including the first electroplating chamber, in the first electroplating tool, and wherein the second electroplating chamber may be in a second electroplating tool that does not share the one or more stations and/or mechanisms of the first electroplating tool.

In some embodiments, operation (a) and operation (b) are performed in a single electroplating chamber. Further, in certain embodiments, the first and second electroplating solutions are flowed sequentially, first for operation (a) and then for operation (b), into the single electroplating chamber.

In some embodiments, the features are holes in a layer of photoresist on the substrate. Electroplating the metal in operations (a) and (b) may form metal pillars in the holes. Further, in certain embodiments, the metal pillars may be a component of wafer level packaging. A contact may be formed between the metal pillars and a tin silver composition. In certain embodiments, the features are holes or trenches having diameters or widths of at least about 150 micrometers.

In some embodiments, the features are holes or trenches having diameters or widths of at least about 200 micrometers.

### BRIEF DESCRIPTION OF THE DRAWINGS

Numerous exemplary embodiments will now be described in greater detail with reference to the accompanying drawings wherein:

FIGS. 1A-1D are schematic cross-sectional views of a substrate undergoing processing.

FIG. 2 is a process flow diagram for electroplating metal into features recessed in a through-mask on a substrate in accordance with certain embodiments disclosed herein.

FIG. 3 shows a schematic cross-sectional view of copper transport phenomena observed at the bulk electrolyte and mask or photoresist interface.

FIG. 4 is a graph of an exemplary model concentration profile indicating copper concentration in a bulk electrolyte as a function of distance.

FIG. 5 is a process flow diagram for electroplating metal into features recessed in a through-mask on a substrate in accordance with certain embodiments disclosed herein.

FIGS. 6A and 6B show an exemplary semiconductor wafer, die and feature and an enlarged section of the wafer, respectively.

FIGS. 7A, 7B and 7C are schematic cross-sectional views of substrates illustrating determination of within-die (WID), within-wafer (WIW), and within-feature (WIF) non-uniformity, respectively.

FIG. 8A is a graph of the solubility limits of copper sulfate (CuSO₄) and sulfuric acid (H₂SO₄) solutions. FIG. 8B is a graph of the solubility limits of copper sulfate in methanesulfonic acid (MSA) compared to the solubility limits of copper sulfate in sulfuric acid.

FIGS. 9A-9C are bar graphs showing improvements in feature non-uniformity for WID, WIW and WIF, respectively.

FIGS. 10A-10C are process flow diagrams for various processes regarding electroplating.

FIG. 11 is a schematic diagram of a tools used for electroplating metal into features in accordance with certain embodiments disclosed herein.

### DETAILED DESCRIPTION

In the following detailed description, numerous specific implementations are set forth in order to provide a thorough understanding of the disclosed implementations. However, as will be apparent to those of ordinary skill in the art, the disclosed implementations may be practiced without these specific details or by using alternate elements or processes. In other instances, well-known processes, procedures, and components have not been described in detail so as not to unnecessarily obscure aspects of the disclosed implementations.

Methods and apparatuses for producing acceptable feature non-uniformity of metal pillars and/or bumps on semiconductor substrates in wafer-level-packaging (WLP) applications are provided herein. Wafer-level packaging, as generally understood by those skilled in the art, refers to the technology of packaging an integrated circuit (IC) while it is still part of the wafer, in contrast to conventional methods of slicing a wafer into individual circuits (dice) and then packaging them.

Electroplating through a lithographic mask, or photoresist (PR), is often used to form metal bumps and pillars in advanced semiconductor device fabrication. A typical process using through-mask electroplating may involve the following process operations. First, a substrate (e.g., a semiconductor substrate having a planar exposed surface) is coated with a thin conductive seed layer material (e.g., Cu) that can be deposited by any suitable method, such as physical vapor deposition (PVD). Next, a non-conductive mask layer, such as a PR, is deposited over the seed layer and is patterned to define recessed features (e.g., round or polygonal holes). The patterning exposes the seed layer at the bottom of each recessed feature. After patterning, the exposed surface of the substrate includes portions of non-conductive mask in the field region, and conductive seed layer at the bottom portions of the recessed features.

Through-mask electroplating (or, in the case of usage of a PR, through-resist electroplating) may involve positioning of the substrate in an electroplating apparatus such that electrical contact is made to the seed layer at the periphery of the substrate. The apparatus houses an anode and an electrolyte that contains ions of a metal intended to be used for plating. The substrate is cathodically biased and immersed into an electrolyte solution, which provides metal ions that are reduced at the surface of the substrate, as described in the following equation, where M is a metal (e.g., copper), and n is the number of electrons transferred during the reduction:

Mⁿ++ne⁻→M⁰

Because the conductive seed layer is exposed to the electrolyte solution only at the bottom portions of the recessed features, electrochemical deposition, e.g. as facilitated by a through-mask electroplating process, occurs only within the recessed features, and not on the field, e.g. a top layer of the mask or PR exposed to the electrolyte solution. Thus, through-mask electroplating may be used to at least partially fill a number of recesses embedded in the mask with metal. Finally, after electroplating, the mask or PR may be removed by a conventional stripping method to thus result in the substrate having a number of free standing metal bumps or pillars.

### Definitions

In this description, the term “semiconductor wafer” or “semiconductor substrate,” or simply “substrate” refers to a substrate that has semiconductor material anywhere within its body, and it is understood by one of skill in the art that the semiconductor material does not need to be exposed. The semiconductor substrate may include one or more dielectric and conductive layers formed over the semiconductor material. A wafer used in the semiconductor device industry is typically a circular-shaped semiconductor substrate, which may have a diameter of 200 mm, 300 mm, or 450 mm, for example. The following detailed description describes electrochemical plating, also referred to as “electroplating” or “plating” for short, and the subsequent etching of material plated on a wafer. However, one skilled in the art will appreciate that suitable alternative implementations of that described herein exist, and that the disclosed electroplating operations may be conducted on work pieces of various shapes and sizes, and which are made from various materials. In addition to semiconductor wafers, other work pieces that may take advantage of the disclosed implementations include various articles such as printed circuit boards (PCBs) and/or the like.

Methods and apparatuses provided herein may be used to produce acceptable feature non-uniformity of metal electro-deposited in recessed features formed in a through-mask or PR provided on a semiconductor substrate, e.g. the metal being deposited in the form of metal pillars and/or bumps. Examples of metals that may be used include: copper (Cu), nickel (Ni), cobalt (Co), tin (Sn), and various alloys thereof. In certain embodiments, alloys of the listed metals include those formed with, e.g., noble metals, e.g. gold (Ag), where the noble metal is present in a small quantity, e.g., at 5 atomic % or less.

The term “feature” as used herein may refer to an unfilled, partially filled, or completely filled recess on a substrate. Likewise, the term “through-mask features” refer to unfilled, partially filled or completely filled recessed features formed in a dielectric mask layer, such as in a photoresist (PR) layer. Such through-mask features are formed on a conductive seed layer. Thus, substrates having unfilled or partially filled through-mask features may include an exposed discontinuous metal layer and an exposed dielectric layer. In certain embodiments, the exposed discontinuous metal layer may be electrically connected by an additional conductive layer positioned beneath the dielectric layer.

Plating of a Single Metal Using Multiple Baths

Methods and apparatuses disclosed herein involve electrochemically depositing, e.g. electroplating, a particular metal (e.g., copper) in features by sequentially contacting features on a substrate, for example as used in WLP, to at least two different electroplating baths during the electroplating process. Usage of two, or more, electroplating baths, where each bath has a distinct concentration of the desired plating metal relative to acid in solution, improves or at a minimum balances various competing process qualities. For instance, process qualities such as within-die (WID) uniformity, within-feature (WIF) uniformity, within-wafer (WIW) uniformity, electroplating speed, and electroplating purity may each, or all, be improved and/or optimized. As referred to herein, the terms “non-uniformity” and “uniformity” generally refers to observed variation of the thickness of metal plated upon a target feature on a substrate. Thus, improvement of non-uniformity involves reducing unwanted variation of at least one process quality, e.g. WID. Further, and unlike chemical mechanical polishing (CMP), the provided methods do not rely on the use of a mechanical pad, or abrasive slurries for uniformity improvement. Rather, the methods rely on contact of the feature to be plated at least two different electroplating baths, where each bath has a chemical composition distinct from the other.

Typically, copper is electroplated onto, or within, features defined in PR-coated silicon wafers from a plating bath to produce pillars for WLP applications. Copper provided by copper sulfate in solution with, for example, sulfuric acid in a plating bath is selected to provide an acceptable plating performance, which may be measured by WID, WIW and WIF at an acceptable plating rate. For many electroplating applications, exposure of a wafer to a single plating bath is sufficient to achieve desirable feature uniformity at an acceptable plating rate. However, for more demanding applications, such as those involving high-aspect ratio features, shortcomings associated with traditional, one-bath approaches may be addressed by employing a multiple-bath plating approach.

The processes described herein can be applied to fill through mask features during fabrication of a variety of packaging interconnects with features of various sizes, including copper wires, redistribution lines (RDL), and pillars of different sizes. Such pillars may include: micro-pillars, standard pillars and integrated high density fan-out (HDFO) and megapillars. The feature widths (or diameters in the case of substantially cylindrically-shaped features) can vary substantially, e.g., from about 5 μm (RDL) to about 200 μm (megapillars). Some disclosed methods may be particularly useful for electroplating larger features, such as for features with widths from about 100-300 μm. For example, the methods can be used during fabrication of a substrate with a plurality of megapillars having widths on the order of about 200 μm. The aspect ratios of features can vary, and in some embodiments are from about 1:2 (height to width) to 2:1, and greater. Some disclosed methods are particularly useful for high aspect ratio features, e.g., about 4:1 and greater. In addition, provided methods are useful for substrates containing features of different sizes. For example, the substrate may contain a first feature having a first width and a feature having a second width that is at least about 1.2 times, such as at least 1.5 times, or at least 2 times greater than the second widths. Substrates having isolated features and/or features having different widths benefit substantially from the disclosed methods, given the variability in metal thickness distribution of such substrates.

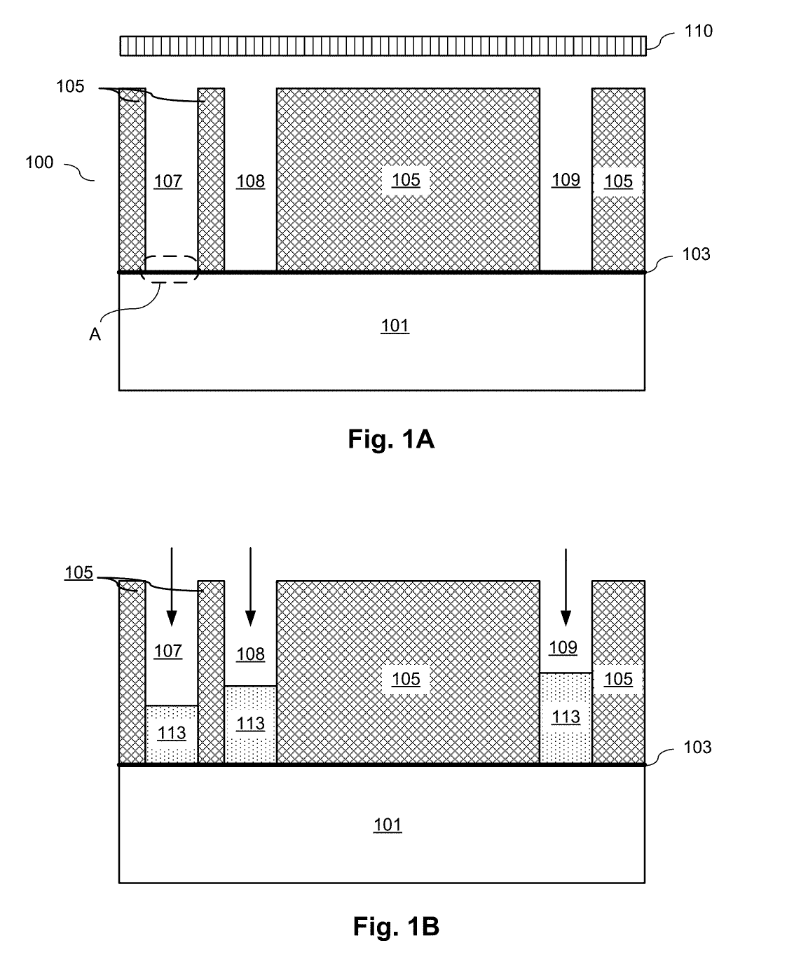

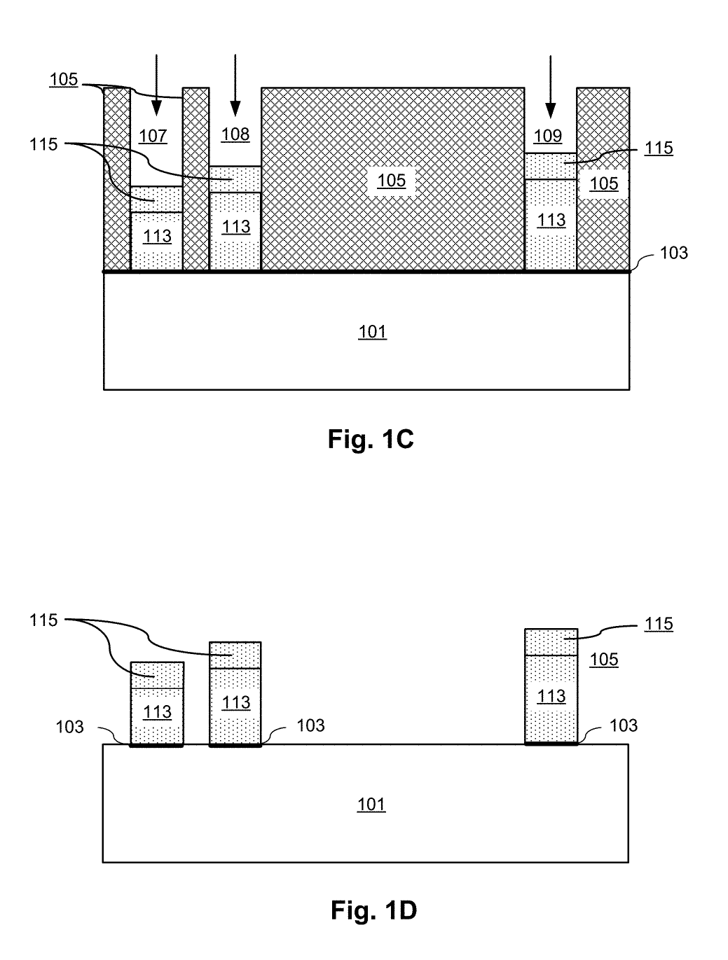

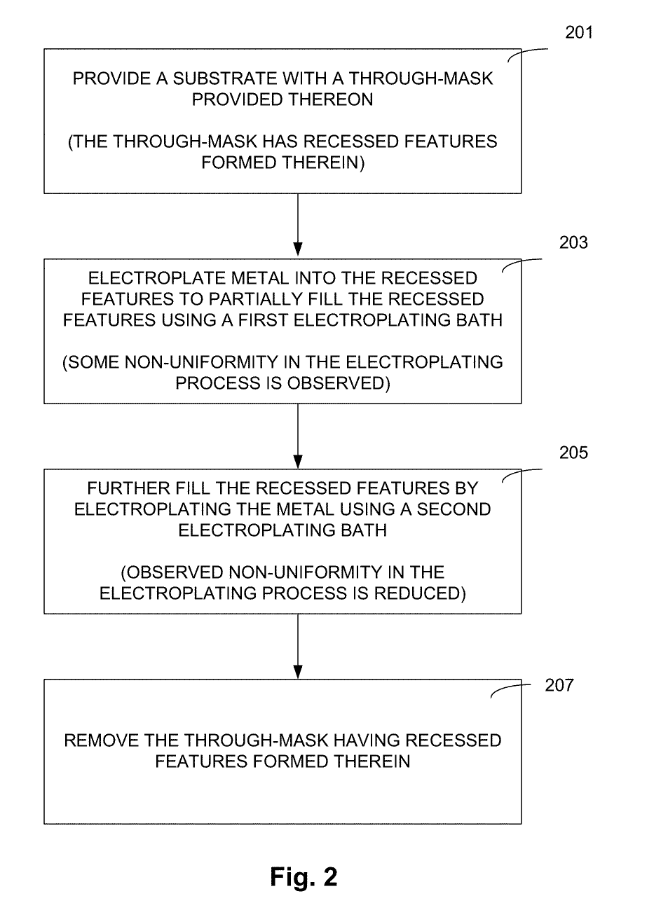

FIGS. 1A-1D show schematic cross-sectional presentations of a portion of a semiconductor substrate undergoing processing, e.g. as indicated by the process flow diagram shown in FIG. 2. The process shown in FIG. 2 initiates at operation 201 with the provision of a substrate with a through-mask provided thereon. The through-mask has features formed therein. FIG. 1A illustrates a cross-sectional view of a portion of such substrate 100, where the substrate includes layer 101 (e.g., a dielectric layer, such as silicon oxide), having a conductive seed layer 103, such as a copper layer, disposed thereon. It will be understood by one skilled in the art that layer 101 may reside over one or more other layers (not shown in the Figures), which may include semiconductor material, such as silicon (Si), germanium (Ge), silicon germanium (SiGe), etc. A patterned non-conductive through-mask, also referred to as mask layer 105 (e.g., PR) is provided on the seed layer 103, and has a plurality of recessed features formed in the mask such the conductive seed layer 103 material is exposed at the bottom portions A of recessed features 107 and 108. Features 107 and 108 are referred to as through-mask recessed features for being formed through the mask layer 105.

In the configuration shown in FIG. 1A, features 107 and 108 are shown as being disposed proximate to each other. In certain embodiments, isolated recessed feature 109, for example, may be located at a greater distance from its closest recessed feature 108. Methods discussed herein are applicable for filling features 107 and 108, as well as isolated feature 109 with metal. The relative isolation of a particular feature is not necessarily relevant to the feature's ability to be filled with metal via the electroplating methods discussed herein.

In certain embodiments, the substrate shown in FIG. 1A may be produced by providing a semiconductor substrate with exposed supporting layer 101 (e.g., a dielectric layer). A conductive layer, e.g. seed layer 103, may be deposited over the exposed supporting layer 101 by any suitable method (e.g., physical vapor deposition (PVD)). Mask layer 105 may then be deposited over seed layer 103 by, for example, spin-coating. Mask layer 105 may be later patterned by a photolithographic technique to define through-mask recessed features 107, 108, and 109. The dimensions of the recessed features may vary depending per application, and may typically have widths of between about 5-250 μm, and aspect ratios of between about 1:2-15:1. In certain embodiments, attaining acceptable non-uniformity for the WID, WIW and WIF metrics may prove especially difficult at high plating rates required for large, e.g. greater than 200 μm tall, pillar applications.

Next, metal is electroplated, e.g. by contacting substrate 100 with one or more electroplating baths, into recessed features 107, 108, and 109 to at least partially fill the recessed features. In certain embodiments, during electroplating, substrate 100 may be cathodically biased by seed layer 103 exposed, as shown in FIG. 1A, and connected to a power supply (not shown in the figures). Substrate 100 may be placed into an electroplating cell opposite anode 110, which is depicted in closer proximity to the substrate and photoresist than is necessarily used in practice. Further, the contact surface of an electrolyte solution surrounding substrate 100 includes ions of the metal to be plated on, for example, seed layer 103. Substrate 100 may be immersed into the electrolyte to initiate electroplating to at least partially fill recessed features 107, 108, and 109 with metal.

Measures taken to improve electroplating uniformity do not necessarily lead to acceptable feature uniformity at an acceptable deposition rate. Thus, further improvement of, for example, WID, uniformity is often desired. Moreover, faster electroplating rates often may lead to increased thickness variability of material deposited within a recessed feature. Accordingly, to achieve a desired target uniformity of electroplated metal pillars and/or bumps, process conditions or parameters may need to be adjusted between electroplating the substrate at a slower rate, or electroplating at a faster rate and later electroplanarizing, e.g. the masking or covering certain regions of a substrate surface during electropolishing. Usage of the disclosed methods allows for higher throughput for a given desired feature uniformity level.

The process flow shown in FIG. 2 employs a first electroplating bath and a second electroplating bath. In certain embodiments, each bath has a unique chemical composition that is different from the other. The respective compositions of the two baths, when used in the same electroplating process, improve the uniformity, or at least one measure of uniformity, of the electroplated features. In some cases, the compositions of the two baths are chosen to achieve a target uniformity of the electroplated metal layer. In certain embodiments, one or both of the plating baths includes metal ions, e.g. copper ions, solvent, and acid.

Conventionally, in copper electroplating, a single plating bath is designed and used to produce acceptable WID, WIW and WIF levels of feature non-uniformity by controlling the concentrations of copper and acid in the bath, as well as the selection and addition of an additive package. However, achieving acceptable feature non-uniformity at the higher plating rates often required for large, or tall, pillar applications is often difficult, or even impossible in certain circumstances, where copper transport limitations may demand the use of a high copper concentration electrolyte to prevent electroplating failures at, or near, the bottom of the feature. Unfortunately, having a high copper concentration will limit the maximum acid concentration, which can, in turn, have a detrimental effect on WID and WIW.

Challenges associated with choosing between high concentrations of copper electrolyte or acid in solution in the electroplating bath may be addressed by using multiple electroplating baths. To reach desirable uniformity levels, features on the substrate or wafer may be electroplated using multiple electroplating baths. Each of the electroplating baths may be formulated to have a unique concentration of the metal intended for use in plating hard-to-reach features, and acid, which, together, favorably influences WID, WIF, and WIW uniformity. For instance, initially, electroplating may be conducted by contacting the features with a first electroplating bath containing, for example, a high copper electrolyte concentration. During electroplating, the high copper concentration will also allow for copper transport to otherwise hard to reach areas within recessed high-aspect ratio features, e.g. 60 μm in diameter and 240 μm tall. It has been found that high copper concentration baths reduce WIF non-uniformity, but can result in a high WID and WIW non-uniformity. Next, the features are contacted with a second electroplating bath with a high-acid concentration for improving WID and WIW during electroplating. Even if copper transport is not a limiting factor, one of the two baths may be prepared to optimize WIF uniformity (which is improved by high copper concentrations), and the other to optimize WID and WIW uniformity (which are improved by high acid concentrations). Accordingly, multiple electroplating baths, each having a metal and acid concentration different from the other baths, may be used serially for electrodeposition of, e.g., large, or tall, pillars exceeding 150 μm in height and particularly high aspect ratio pillars (e.g., having a ratio of height to diameter of at least about 3, or at least about 4). Further, the baths may be prepared such that a long plating duration (e.g., greater than 10 min.) does not adversely, or significantly, impact total system overhead (e.g., rinses, transfers) and throughput.

The process flow shown in FIG. 2 further illustrates that described above, namely using a multi-bath electroplating approach to plate a single metal, e.g., copper, on features of a substrate. In operation 201, as described above, a substrate with a through-mask thereon is provided. The through-mask, such as a patterned PR, may be, for example, deposited or applied to the substrate by traditional techniques such as by spin-coating. The through-mask provided on the substrate has recessed features formed therein intended to be filled with a metal by electroplating, e.g. as shown in FIGS. 1A-1D. Next, at operation 203, metal is electroplated into features recessed in the through-mask to partially fill the recessed features. Features of the substrate are contacted with a first electroplating bath having a defined concentration of metal ions, e.g., copper ions in solution with acid. The concentration of the metal ions in solution may be dictated by a need for rapid copper ion transport deep into tall and/or high-aspect ratio features in the through-mask. In certain embodiments, some non-uniformity in the electroplating process conducted at operation 203 is observed.

Operation 203 corresponds to FIGS. 1A and 1B, where features 107, 108 and 109 formed in mask layer 105 are filled with metal, e.g., copper, upon contacting seed layer 103 with the first electroplating bath and applying a current. As shown in FIG. 1B, some non-uniformity in the height of metal 113 within features 107, 108 and 109 is observed and may result from the composition of the first electroplating bath. As generally discussed earlier, such a high copper concentration may, in turn, limit acid content in the bath, resulting in observed WID and WIW non-uniformity.

To minimize further non-uniformity of electroplated metal 113 as shown in FIG. 1B, the substrate is next contacted with a second electroplating bath that has a composition different from the first electroplating bath, e.g., with a relatively higher acid concentration to improve WID and WIW non-uniformity caused by the first electroplating bath with a high copper concentration. Supplemental metal 115, e.g., copper, is electroplated from the second electroplating bath to further fill recessed features 107, 108 and 109 such that the observed non-uniformity between the features is less than the non-uniformity produced if all of the electroplating were done in the first bath as shown in FIGS. 1B and 1C. As shown in FIGS. 1C and 1D, the second electroplating bath deposits a substantially uniform quantity of supplemental metal 115 on each of the pillars of metal 113, such that each pillar becomes taller by approximately the same amount. Rather than creating pillars from metal 113 of the first electroplating bath alone, the method deposits supplemental metal 115 on pillars formed from metal 113 using the second electroplating bath that has qualities not found in the first electroplating bath. For instance, the composition of the second electroplating bath may be selected to promote electroplating uniformity, while the concentration of metal ion in the first electroplating bath may be selected to promote electroplating speed and performance. In another example, the composition of the second electroplating bath is chosen to improve one type of non-uniformity while the composition of the first electroplating bath is chosen to improve a different type of non-uniformity. Accordingly, the two-bath electroplating approach disclosed herein offers desirable attributes of each of the individual electroplating baths used in a strategic manner, e.g. the first electroplating bath for plating efficiency, the second bath for attaining hard-to-reach height tolerances and/or precise height targets.

In some implementations, relative non-uniformity levels observed in multi-bath electroplating approaches may be explained algebraically. For instance, non-uniformity observed while filling features to form pillars therein by metal 113 from the first electroplating bath may be quantified as “x.” Similarly, non-uniformity resultant from plating upon contact of said features with supplemental metal 115 may be quantified as “y.” Thus, total non-uniformity defined as the addition of the respective non-uniformities observed upon plating with the first and second baths may be expressed as “x+y.” This is in contrast to conducting two sequential plating operations with the first bath alone, which may be expressed as “x+x=2*x.” To yield an improvement over electroplating using only one bath, e.g. the first bath, the second electroplating bath must be selected with a value of “y” that is lower than “x,” thus resulting in a comparative relationship of “x+y<2*x.”

In certain unique cases, the second electroplating bath may demonstrate a “negative” type of non-uniformity, i.e., the first electroplating bath produces non-uniformity in a given direction (e.g., less plating in more densely spaced features) but the second electroplating bath produces non-uniformity in the opposite direction (e.g., less plating in more isolated features). Such cases clearly meet the criterion: x+y<2*x.

In some embodiments, the first and/or second electroplating baths used in operations 203 and/or 205, respectively, may employ additives that modify the kinetics of deposition (or plating) on different surfaces of the features. Further, electroplating may be conducted in a solution containing one or more of an electroplating suppressor and/or one or more of an electroplating leveler.

After electroplating metal using the second electroplating bath at operation 205, mask layer 105 is removed at operation 207 to conclude the process flow shown in FIG. 2. In certain embodiments, mask layer 105 is a PR that can be removed by PR stripping, or any other suitable technique. Removal of mask layer 105 at operation 207 results in substrate 101 having a plurality of metal bumps and/or pillars formed from metal 113, as shown in FIG. 1D. Also, and as shown in FIG. 1D, seed layer 103 can be removed in a subsequent etching operation.

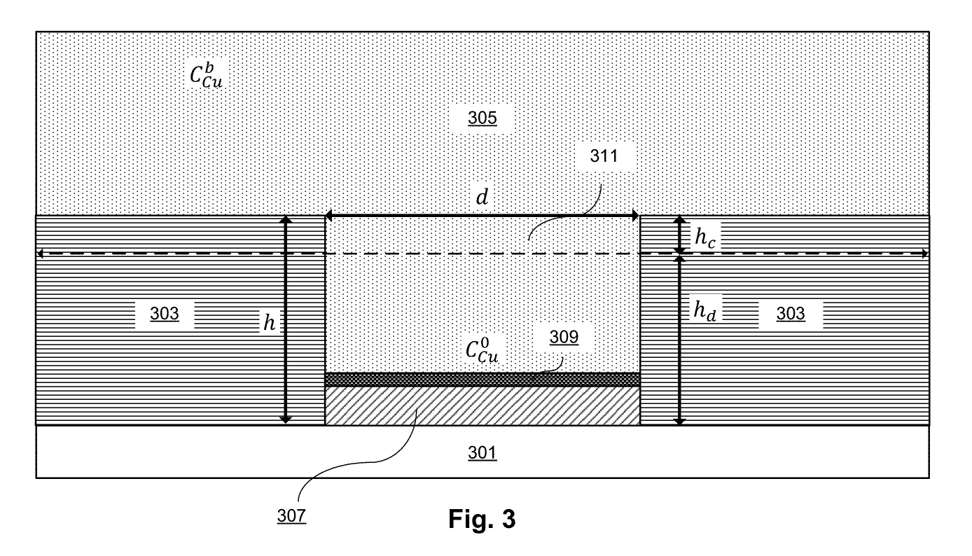

To explain mass transport issues associated with electrodeposition in high aspect ratio features, a detailed cross-sectional view of a substrate 301 with a PR layer 303a provided thereon is shown in FIG. 3. Features, such as feature 311, are defined by an aspect ratio calculated by dividing the depth or height of the feature by its width. Exemplary high-aspect ratio features include semiconductor contacts that are narrow relative to their depth, trenches that are narrow relative to their depth, and/or metal lines that are tall relative to their width.

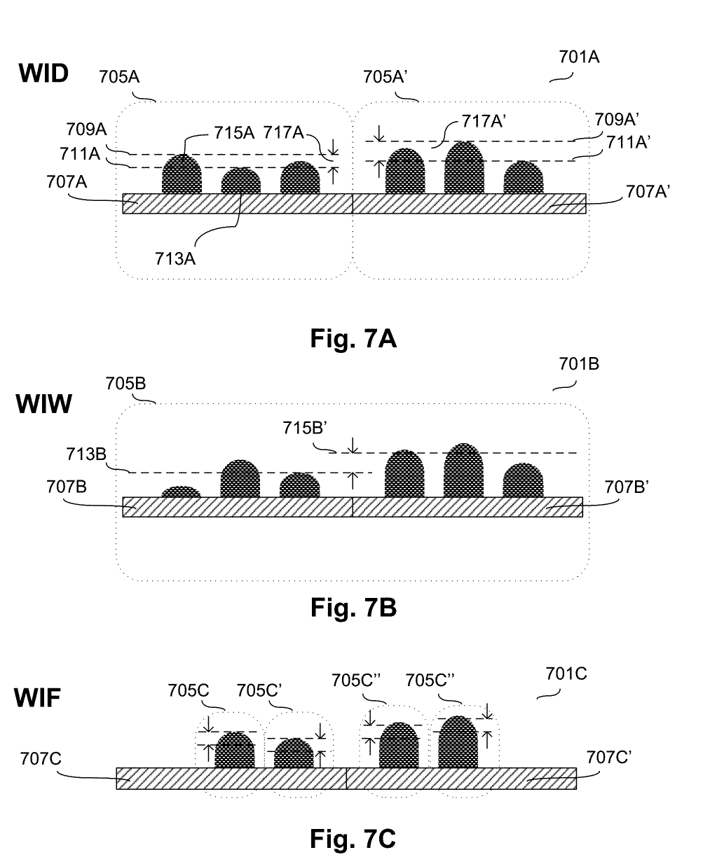

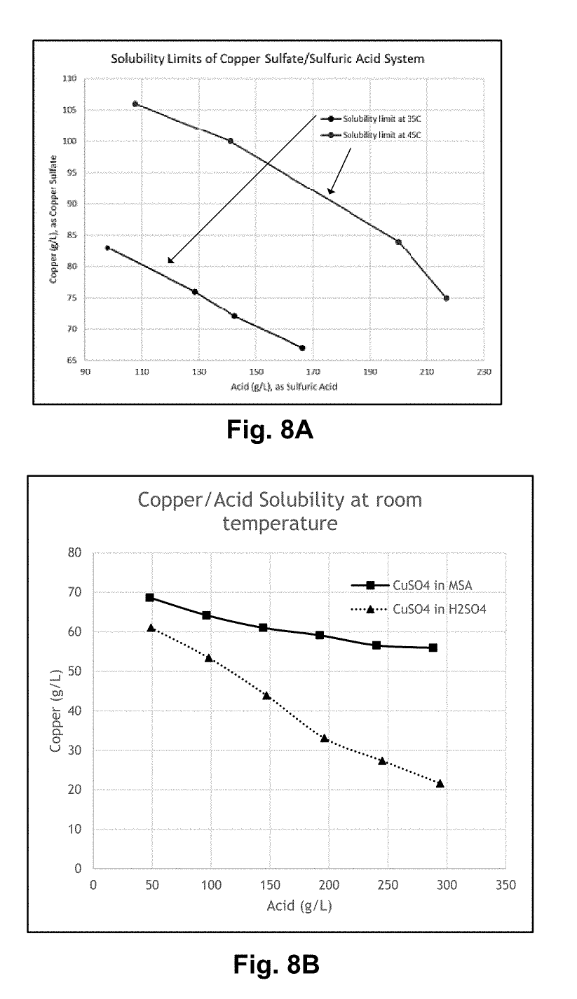

Issues affecting such high-aspect ratio features include relative difficulty in filling hard to reach areas due to the diffusion rate of the metal ions used for plating, e.g., copper. Increasing the concentration of metal ions in solution limits acid concentration in the bath due to sharing of a common anion (to be explained in further detail in connection with FIGS. 7 and 8). Low acid content typically has a corresponding detrimental effect on achieving acceptable WID and WIW non-uniformity. Usage of a second electroplating bath of a different chemistry than the first, as shown in operation 205 in FIG. 2, addresses issues in choosing bath chemistries based on optimizing a particular feature parameter, e.g. WID and WIW, or WIF, for instance.

Further, issues of achieving desirable feature uniformity must often be balanced against throughput considerations, e.g., electroplating rates in a production setting. Typical causes contributing to a low plating rate may stem from a variety of issues. For instance, high plating rates may prevent the achievement of acceptable WID, WIW, and WIF non-uniformity on WLP pillars. Plating rates are also limited by a “limiting plating rate,” which is defined as the point at which all of the metal ions, e.g. copper ions that reach the feature surface are plated. The limiting plating rate is necessarily affected by the concentration of metal ions present in the bulk electrolyte solution (plating bath). It is also affected by the metal ion transport conditions, which are affected by the geometry of a recessed feature; e.g., a high aspect ratio feature impedes metal ion transport to the bottom of the recessed feature.

Outside of being impacted by plating rates as described above, feature uniformity is also impacted by other factors. For instance, high WID and WIW non-uniformity is often caused by, among other factors, high solution resistance relative to the surface resistance at the plating surface, thus preventing efficient metal transport through the solution. To lower WID and WIW non-uniformity, the plating bath may be made more conductive by using a high concentration of, e.g., an acid such as sulfuric acid (H₂SO₄). Alternatively, surface resistance of features may be increased through the addition of certain plating additives such as levelers. In contrast to factors contributing to high WID and WIW non-uniformity, high WIF non-uniformity may be caused by low copper ion content in the plating solution. Accordingly, to lower WIF non-uniformity, the process may employ a plating bath having a high concentration of copper ions provided by, e.g., copper sulfate (CuSO₄) and/or leveling additive packages that must be added to the plating bath. Also, such additive packages may be oriented toward decreasing WID, while others may be better suited to decrease WIF. Still further, the solubility of certain metals in acids are limited, or influenced, by sharing a common anion such as copper sulfate and sulfuric acid, which share the sulfate (SO₄) anion.

Using multiple sequential electroplating baths, each bath varying in composition but containing a common metal ion, e.g. copper ion, allows for electroplating at acceptable plating rates while producing features, such as pillars made of metal 113 as shown in FIG. 1D, at acceptable levels of WID, WIW and WIF non-uniformity.

Metal Ion Transport

FIG. 3 shows copper transport into feature 311 from a bulk solution 305 having a defined copper concentration C_{Cu}^{b}, which, in certain embodiments, may range from about 28-60 g C²⁺ per liter of electrolyte. Bulk solution 305 is assumed to have a constant concentration C_{Cu}^{b} at an infinite distance from the substrate 301 or PR 303a. In contrast, the solution at or near the interface with the exposed substrate 301 within feature 311 has a lower copper concentration C_{Cu}⁰, which at the limiting plating rate will have zero copper in solution with electrolyte.

Feature 311 is shown with a defined height, h, and width or diameter, d. Copper ion transport may be dominated by convection within a defined fraction h, of feature 311, but dominated by diffusion in the remainder h_{d} of the feature. The point at which copper transport transitions from being dominated by convection to diffusion is determined primarily by the velocity of bulk electrolyte 305 over feature 311 and the feature aspect ratio. For instance, a higher bulk velocity will cause deeper solution recirculation within the feature, thus convective copper ion transport may dominate in a large portion of the feature. A feature 311 with a smaller diameter d may have a higher aspect ratio and limit recirculation of solution within the feature, thus causing copper ion transport over more of the feature to be dominated by diffusion.

In certain embodiments, partial metal pillar 307 is formed upon contacting feature 311 with the first electroplating bath used in operation 203 of the process flow shown in FIG. 2. Next, feature 311 may be contacted with another bulk solution 305 which may correspond with the second electroplating bath used in operation 205 to fill additional metal 309 to reach a desired height as described above with regard to acceptable WID, WIW and WIF non-uniformity.

Copper transport in the diffusion-dominated region indicated by h_{d} in FIG. 3 may be modeled by Fick's First Law of Diffusion:

$${J}_{Cu} = - {D}_{Cu} \frac{{dC}_{Cu}}{dz} \qquad ( Eq . 1 )$$

In Eq. 1 shown above, differential

$$\frac{{dC}_{Cu}}{dz}$$

indicates change in metal ion, e.g. copper ion, concentration per unit height, D_{Cu} is a constant diffusion coefficient, or diffusivity, with respect to a location within the feature, e.g. feature 311 as shown in FIG. 3, and J_{Cu} is the “diffusion flux,” of which the dimension is the amount of substance, e.g. copper, per unit time per unit area. Diffusion flux may be expressed in such units as mol m⁻²s⁻¹. Solving appropriately for copper concentration at a specific vertical height yields the following equation:

$${C}_{Cu} = {C}_{Cu}^{b} + \frac{{J}_{Cu}}{{D}_{Cu}} ( {h}_{d} - z ) \qquad ( Eq . 2 )$$

In Eq. 2 shown above, C_{Cu} represents copper concentration at a specific height location z within the diffusion-dominated region indicated by h_{d} that is determined by feature geometry. C_{Cu}^{b}, as shown above in Eq. 2 and introduced earlier, refers to the copper ion concentration of the bulk electrolyte at a theoretical infinite distance above the substrate upon which plating is intended. Since h_{d} is determined by feature geometry, a high C_{Cu}^{b} may be required to reach an acceptable limiting current, or limiting plating rate.

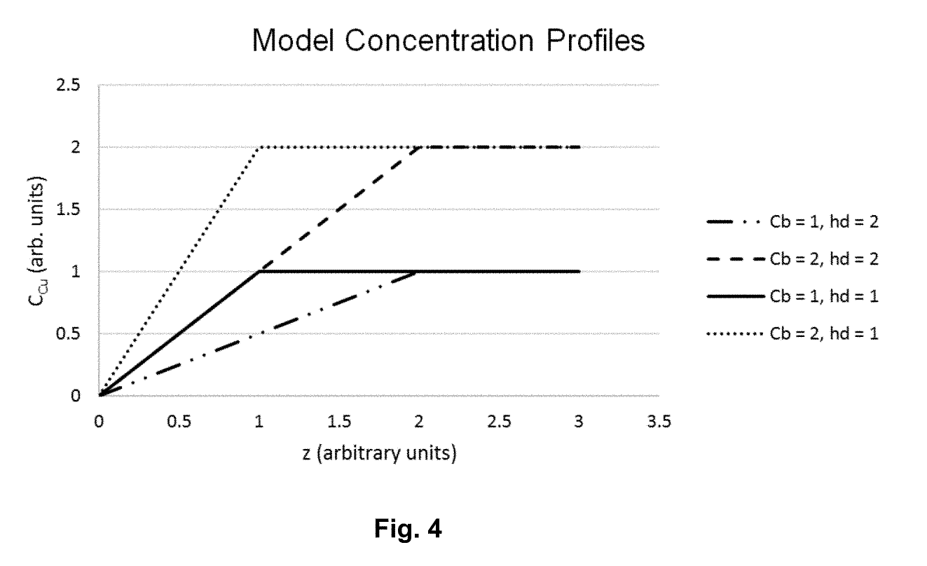

Copper ion transport illustrated in FIG. 3 is described in the plot shown in FIG. 4 as a function of distance z from the substrate-bulk solution interface, e.g., where substrate 301 contacts bulk solution 305 within feature 311. Table 1 further provides information regarding various combinations of C_{Cu}^{b}, h_{d}, and limiting current shown in FIG. 4.

TABLE 1

| | | Limiting |
|---|---|---|
| C_{Cu}^{b} | h_{d} | Current |
| Low (1) | Large (2) | Low (0.5) |
| High (2) | Large (2) | Moderate (1) |
| Low (1) | Small (1) | Moderate (1) |
| High (2) | Small (1) | High (2) |

As observed, various combinations of the initial bulk copper concentration, e.g. at a theoretical infinite distance, may influence C_{Cu} as a function of distance z from the substrate-bulk solution interface, e.g. at “0” C_{Cu} and z. As explained, features with higher aspect ratios will have correspondingly higher diffusion-dominated regions h_{d}, which in turn may require, or otherwise benefit from, a higher C_{Cu}^{b}. For instance, the limiting current, which may be proportionate to the slope of the lines shown in FIG. 4, is the same for conditions of C_{Cu}^{b}=2 and h_{d}=2 as well as C_{Cu}^{b}=1 and h_{d}=1, indicating that a lower copper concentration in bulk may still be used to effectively plate features with lower diffusion-dominated regions.

Processes and Baths for a Multi-Bath Electroplating Approach

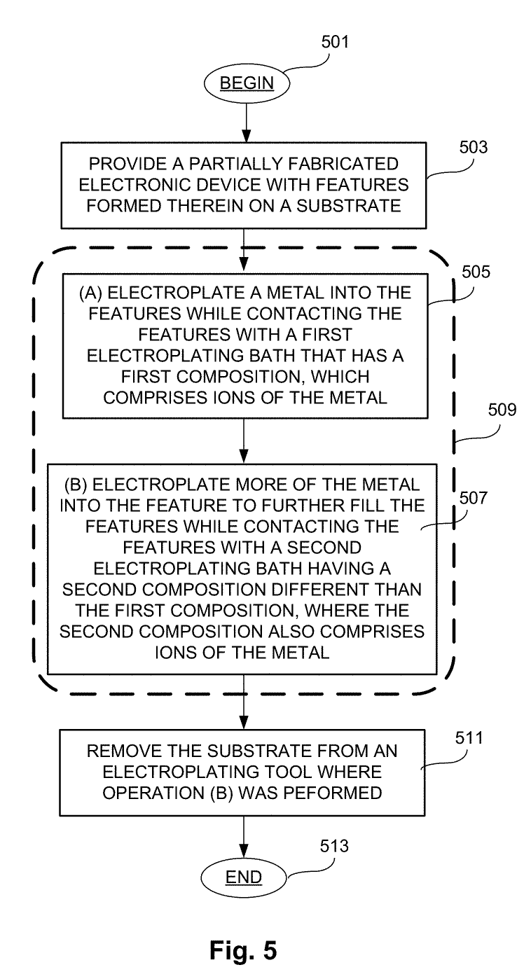

FIG. 5 shows a process flow which relates to the discussion of FIGS. 2 through 4. The process flow of FIG. 5 begins at operation 501. Next, a partially fabricated electronic device with features formed therein is provided on a substrate at operation 503. The electronic device may be a through-mask, or PR, as discussed earlier. Features intended to be plated by that shown in FIG. 5 are then partially filled with a metal, e.g. copper, by contacting the features with a first electroplating bath that has a first composition, which has ions of the metal. Next, at operation 507, the substrate is contacted with a second electroplating bath having a second composition different than the first composition. The second electroplating bath also has ions of the same metal of the first electroplating bath and may be tailored as needed to achieve acceptable non-uniformity in WIF, whereas the first electroplating bath may be adjusted to optimize WID and WIW. The substrate is then, at operation 511, removed from the electroplating tool where operation 507 was performed, and the process concludes at operation 513.

Usage of a multi-bath approach as outlined in FIGS. 1-5, allows for optimization of electroplating toward various potentially competing performance metrics at various parts of the electroplating process. For instance, the maximum possible plating rate at the limiting current at the bottom of the feature can be increased by increasing the amount (and thus the concentration) of copper in the electroplating bath.

As the copper plated in the feature forms growing pillars, e.g. of metal 113 and supplemental metal 115 provided thereon as shown in FIG. 1D, the distance that copper must convect and/or diffuse proportionately reduces. Thus, less copper is needed relative to when the electroplating process is initiated, e.g. at operation 501 in FIG. 5 where no copper has been yet plated within the feature at the substrate-plating bath interface, as the metal pillar grows and the distance, e.g. ha, copper must diffuse reduces. The substrate provided at, for example, operation 503 as shown in FIG. 5 and/or operation 201 as shown in FIG. 2, may be plated initially in a high-copper bath, e.g. the first electroplating bath used in operation 505, to both access hard-to-reach areas of high-aspect ratio features and improve WIF non-uniformity, which benefits from high copper concentration levels.

In certain embodiments, the first electroplating bath used in operation 505 may have a concentration level of about 85 grams per liter (g/l) of copper ions (Cu) provided by, for example, copper sulfate (CuSO₄). Generally, higher electroplating rates consume copper at a correspondingly high rate, thus a high copper concentration must be used to enable a high limiting deposition, or plating, rate. The first electroplating bath may also have a concentration of 145 g/l of acid, e.g. sulfuric acid. A high acid concentration increases the conductivity of the first electroplating bath, which will reduce WIW and WID non-uniformity. For electroplating baths made of copper sulfate in solution with sulfuric acid, 145 g/l of acid is the highest acceptable concentration level of acid for 100 g/l of copper ions at a temperature of approximately 45° C., without causing copper to form copper sulfate crystals that precipitate out of solution, e.g. as discussed further in connection with FIG. 8A. In certain embodiments, the first electroplating bath may have a concentration of 50 ppm chloride ions (Cl⁻), which may assist in producing a smooth plated copper surface. Further, in certain embodiments, an Intervia™ 9000 additive package provided by The Dow Chemical Company may be added to the first electroplating bath to provide for desirable WID and WIW performance. The Intervia™ 9000 additive package may function as a suppressor or accelerator.

After plating using the first plating bath, the substrate may then be moved to a high-acid bath (which improves WID and WIW) once the electroplating passes the point in time where copper diffusion ceases to be a limiting factor, e.g. where pillars formed from the plated metal reach a sufficient height within the feature. Thus, two different chemical compositions of copper and acid with different beneficial qualities (e.g. improvement WID, WIW, or WIF non-uniformity, and/or throughput-related performance, and/or deposition and/or electroplating purity) may be selected in a two-bath electroplating approach to produce superior results.

In certain embodiments, the second electroplating bath used in operation 507 may have a copper concentration of 70 g/l of copper ions, provided by copper sulfate. Electroplating with a high plating rate still requires a significant amount of copper. However, after contacting features on the substrate, or wafer, to the first electroplating bath at operation 505, copper need not diffuse as far into the feature to reach the higher plating surface. Thus, a lower copper concentration can be used for the second electroplating bath. Likewise, the lower copper, e.g. as provided by copper sulfate (CuSO₄), concentration allows for a proportionately higher, e.g. at 190 g/l acid concentration, as described in further detail in FIGS. 8A and 8B, which will improve WIW and WID performance by making the bath more conductive. In certain embodiments, the second electroplating bath may have a chloride ion (Cl⁻) concentration of 50 ppm. In certain embodiments, an Enthone SC additive package provided by MacDermid Enthone, a wholly-owned subsidiary of Platform Specialty Products Corp., may be added to the second electroplating bath to improve WIF non-uniformity. The Enthone SC additive package may function as a leveler.

While many different combinations of plating bath compositions may be employed, various embodiments employ aqueous plating baths in which the first bath has a higher concentration of metal ions than the second plating bath, and the second bath has a higher concentration of acid than the first bath. However, one skilled in the art will appreciate that the opposite may also be true in certain embodiments, e.g., that the first bath has a lower concentration of metal ions than the second bath, and the second bath has a lower concentration of acid than the first bath. Traditionally, in certain embodiments employing copper electroplating, the first bath has a copper ion concentration of between about 24 and 90 g/l or between about 40 and 70 g/l. In such embodiments, the first bath may have a pH of between about −0.34 and 0.26 (e.g., in the form of 60-240 g/L sulfuric acid, or a hydrogen ion concentration in solution of 0.5 M-2.2M) or between about −0.22 and 0 (e.g. in the form of 110-185 g/L sulfuric acid, or a hydrogen ion concentration in solution of 1.0M-1.7M). In such embodiments, the first bath may have a chloride ion concentration of between about 30 ppm and 100 ppm, or between about 50 ppm and 80 ppm. In such embodiments, the second bath may have a copper ion concentration, a pH, and a chloride ion concentration differing from the first bath, but within the same ranges as given above. Either or both the first plating bath and the second plating bath may include one or more plating additives. In certain embodiments, the plating bath that is best for mitigating WIF non-uniformity (e.g., the second bath) has a higher concentration of a leveling additive. In certain embodiments, the plating bath that will deposit the metal that will contact another surface (e.g. the second bath) has plating additives that yield a high-purity film. The roles of additives and examples of them are presented in the discussion below. While embodiments described herein focus on electroplating copper, the disclosure is not limited to copper. Other metals such as nickel, cobalt, tin, and tin-silver alloy may be electroplated using multi-bath embodiments as described herein.

Aside from bath composition, other plating parameters may vary between the two electroplating operations. In certain embodiments, the current density and/or temperature employed with the first electroplating bath is different from that employed with the second electroplating bath. Such changes may impact overall electroplating performance directly or indirectly; e.g., the solubility of metal ions in solution with a given acid may vary with temperature. In certain embodiments, the current density employed with the bath containing a higher metal ion concentration (e.g. the first bath) may be higher than the current density employed with the bath containing a lower metal ion concentration (e.g. the second bath). In certain embodiments, the temperature of the bath containing a higher metal ion concentration (e.g. the first bath) may be higher than that of the bath containing a lower metal ion concentration (e.g. the second bath) to allow for a higher metal ion solubility.

FIG. 8A shows a graph of copper sulfate (CuSO₄) and sulfuric acid (H₂SO₄) solubility limits in water. These compounds are common components of electroplating baths used in copper electroplating. Copper concentration is indicated on the vertical (y) axis, while acid concentration is indicated on the horizontal (x) axis, both in grams (g) per liter (l). Copper sulfate provides the copper intended to be plated onto the substrate or wafer to form features, such as pillars made of metal 113 as shown in FIG. 1D. Sulfuric acid increases the conductivity of the system due to its more mobile hydrogen (H⁺) ion, relative to the copper (Cu²⁺) ion.

Copper sulfate and sulfuric acid share a common anion, the sulfate anion (SO₄²⁻), which accordingly limits the amount of copper sulfate and sulfuric acid that can be in solution at the same time, e.g. as shown in FIG. 8A. Solubility limits of copper sulfate in sulfuric acid are also dependent on temperature, with higher copper sulfate solubility in sulfuric acid observed at higher temperatures. Although increasing the limit of soluble copper sulfate in sulfuric acid, higher temperatures can also damage PR during plating and thus may be undesirable. And, exceeding the saturation point of copper sulfate that may exist in solution with sulfuric acid for a given temperature will cause excess sulfate and copper ions to form copper sulfate crystals, which will form a precipitate. Also, in addition to reducing available copper, precipitating copper sulfate crystals can damage various process equipment associated with multi-bath electroplating as described herein, e.g. vessels, pumps and/or filters.

Although copper sulfate and sulfuric acid may be commonly used electrolyte components, they are not unique, and altering the anion, e.g. sulfate, for one component or the other can affect co-solubility. For example, methanesulfonic acid (CH₃SO₃H), also abbreviated as MSA, does not share a common anion with copper sulfate (CuSO₄). Thus, more sulfate can be dissolved in an MSA solution compared to a sulfuric acid (H₂SO₄) solution with an equal acid concentration, e.g. as determined by mass. However, MSA may demonstrate higher solution resistance, which may lead to increased feature non-uniformity.

FIG. 8B shows a graph of copper sulfate in MSA and copper sulfate in sulfuric acid, with copper concentration (as provided by copper sulfate) on the vertical (y) axis and acid concentration on the horizontal (x) axis, both denoted in (g/L). The graph shown in FIG. 8B was generated from measurement data report by Cho et al., Electrochem. Solid-State Lett. 2011, vol. 14 iss. 5, D52-D56.

Different additive packages may demonstrate different performance enhancements with respect to WID, WIW, and WIF. Some additive packages improve one metric at the expense of one or both of the other metrics. Others may find balance between the three metrics, but do not achieve the level of performance gained by focusing on a single metric. Further, different additive packages may result in different levels of impurities in the plated copper. A more pure copper deposition may be required to minimize the occurrence of, for example, Kirkendall voids at a copper-solder interface, limiting the available additive packages. Also, in certain circumstances, high-purity additive packages may underperform in WIF, as well. Further, copper transport issues, or purity requirements, can further restrict the choice of a particular additive package, or type thereof, which are described in further detail below. The following discussion touches on aspects of different types of additives that can be used with the disclosed embodiments.

Suppressors

While not wishing to be bound to any particular theory or mechanism of action, it is believed that suppressors (either alone or in combination with other electroplating bath additives) are surface-kinetic limiting (or polarizing) compounds that lead to a significant increase in the voltage drop across the substrate-electrolyte interface, especially when present in combination with a surface adsorbing halide (e.g., chloride or bromide). The halide may act as a chemisorbed-bridge between the suppressor molecules and the wafer surface. The suppressor both (1) increases the local polarization of the substrate surface at regions where the suppressor is present relative to regions where the suppressor is absent, and (2) increases the polarization of the substrate surface generally. The increased polarization (local and/or general) corresponds to increased resistivity/impedance and therefore slower plating at a particular applied potential.

It is believed that suppressors are not significantly incorporated into the deposited or plated film, (e.g. forming pillars), though they may slowly degrade over time by electrolysis or chemical decomposition in the electroplating bath. Suppressors are often relatively large molecules, and in many instances they are polymeric in nature (e.g., polyethylene oxide, polypropylene oxide, polyethylene glycol, polypropylene glycol, etc). Other examples of suppressors include polyethylene and polypropylene oxides with S- and/or N-containing functional groups, block polymers of polyethylene oxide and polypropylene oxides, etc. The suppressors can have linear chain structures or branch structures or both. It is common that suppressor molecules with various molecular weights co-exist in a commercial suppressor solution. Due in part to suppressors' large size, the diffusion of these compounds into a recessed feature can be relatively slow compared to other bath components.

Accelerators

While not wishing to be bound by any theory or mechanism of action, it is believed that accelerators (either alone or in combination with other bath additives) tend to locally reduce the polarization effect associated with the presence of suppressors, and thereby locally increase the electrodeposition or electroplating rate. The reduced polarization effect is most pronounced in regions where the adsorbed accelerator is most concentrated (i.e., the polarization is reduced as a function of the local surface concentration of adsorbed accelerator). Example accelerators include, but are not limited to, dimercaptopropane sulfonic acid, dimercaptoethane sulfonic acid, mercaptopropane sulfonic acid, mercaptoethane sulfonic acid, bis-(3-sulfopropyl) disulfide (SPS), and their derivatives. Although the accelerator may become strongly adsorbed to the substrate surface and generally laterally-surface immobile as a result of the plating reactions, the accelerator is generally not significantly incorporated into the film. Thus, the accelerator remains on the surface as metal is deposited or plated. As a recess is filled, the local accelerator concentration increases on the surface within the recess. Accelerators tend to be smaller molecules and exhibit faster diffusion into recessed features, as compared to suppressors.

Levelers

While not wishing to be bound by any theory or mechanism of action, it is believed that levelers (either alone or in combination with other bath additives) act as suppressing agents, in some cases to counteract the depolarization effect associated with accelerators, especially in exposed portions of a substrate, such the field region of a wafer being processed, and at the side walls of a feature.

The leveler may locally increase the polarization/surface resistance of the substrate, thereby slowing the local electrodeposition reaction in regions where the leveler is present. The local concentration of levelers is determined to some degree by mass transport. Therefore levelers act principally on surface structures having geometries that protrude away from the surface. This action “smooths” the surface of the electrodeposited layer. It is believed that in many cases the leveler reacts or is consumed at the substrate surface at a rate that is at or near a diffusion limited rate, and therefore, a continuous supply of leveler is often beneficial in maintaining uniform plating conditions over time.

Leveler compounds are generally classified as levelers based on their electrochemical function and impact and do not require specific chemical structure or formulation. However, levelers often contain one or more nitrogen, amine, imide or imidazole, and may also contain sulfur functional groups. Certain levelers include one or more five and six member rings and/or conjugated organic compound derivatives. Nitrogen groups may form part of the ring structure. In amine-containing levelers, the amines may be primary, secondary, tertiary, or quaternary alkyl or aryl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quonoline, and isoquinoline. Imidazole and pyridine may be especially useful. Another example of a leveler is Janus Green B. Leveler compounds may also include ethoxide groups. For example, the leveler may include a general backbone similar to that found in polyethylene glycol or polyethyelene oxide, with fragments of amine functionally inserted over the chain (e.g., Janus Green B). Example epoxides include, but are not limited to, epihalohydrins such as epichlorohydrin and epibromohydrin, and polyepoxide compounds. Polyepoxide compounds having two or more epoxide moieties joined together by an ether-containing linkage may be especially useful. Some leveler compounds are polymeric, while others are not. Example polymeric leveler compounds include, but are not limited to, polyethylenimine, polyamidoamines, quaternized poly(vinylpyridine), and reaction products of an amine with various oxygen epoxides or sulfides. One example of a non-polymeric leveler is 6-mercapto-hexanol. Another example leveler is polyvinylpyrrolidone (PVP).

Returning to FIG. 5, one skilled in the art will appreciate that described for a two-bath electroplating approach as shown in FIGS. 2 and 5 may be extended to additional electroplating baths depending as required (e.g., three separate plating baths). Accordingly, operation 509 collectively encompasses both operations 505 and 507 to include, whenever required, additional operations involving contact of the substrate to additional electroplating baths. Each additional electroplating bath may have chemistry different from other plating baths, but will include ions of the same metal intended for plating, e.g. copper.

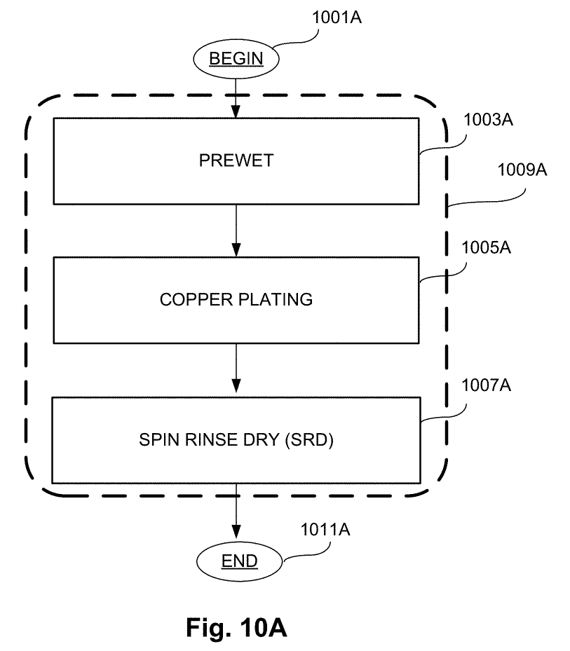

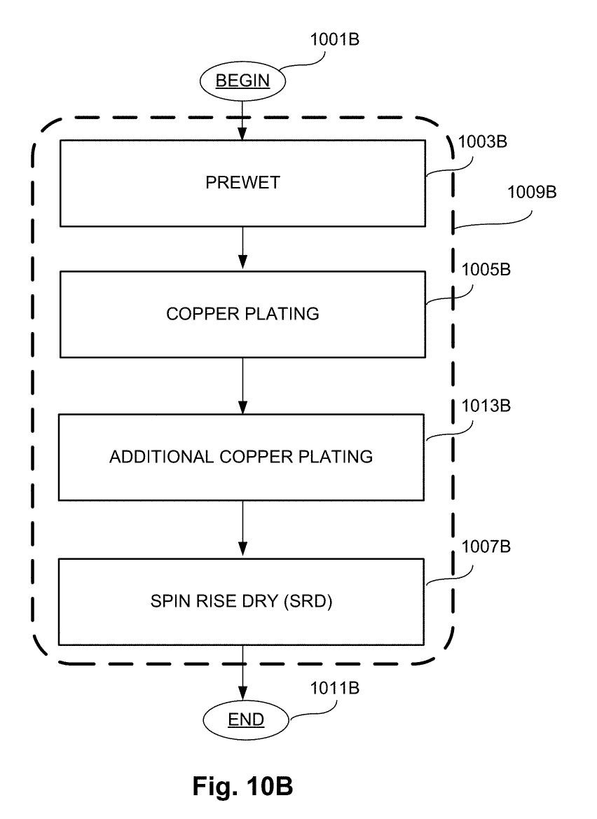

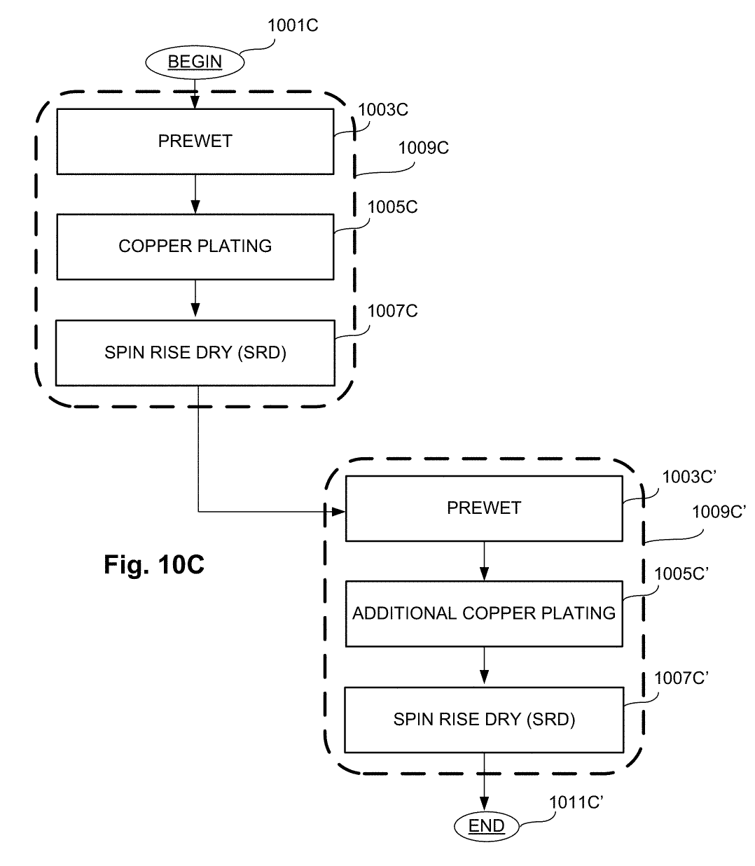

To minimize throughput impact while implementing a multi-bath electroplating approach, the substrate with features intended to be plated may be transferred directly between two (or more) baths on a single tool. Thus, the substrate remains wet between the end of the initial plating process and the beginning of any subsequent plating process. For instance, the Sabre 3D® manufactured by Lam Research Corp., of Fremont, Calif., has multiple plating cells that can be connected to separate baths on a single tool. Thus, a multi-bath plating approach can be implemented on a single tool such as the Sabre 3D® with minimal impact to process throughput, e.g. also as described in the process flow shown in FIG. 10B. However, if this is not possible, separate tools can be used, as shown in FIG. 10C, although doing so may reduce process throughput as the substrate will have to go through pre-wet and SRD twice.

Methods discussed and shown in the Figures have been developed for large (e.g., greater than about 150 μm in height) WLP pillars, where typical plating time are lengthy (e.g., greater than about 10 min). Thus, transfer from one bath to another has little impact on the overall plating time. Regardless, the multi-bath electroplating approach is extendible to other WLP applications and/or pillar dimensions (e.g., 50 um×50 um pillars) where, for example, non-uniformity improvements could still be realized, but the substrate transfer time from one plating bath to another could have a greater impact on process throughput.

Advantages of using a multi-bath electroplating approach as outlined in the process flows shown in FIGS. 2 and 5 are numerous. For instance, by plating in a high-copper bath initially, diffusion of copper into the features is not a limiting factor. Rather, copper plates into recessed features as desired to form metal pillars, e.g. as shown in FIG. 1D. Next, when the distance copper must diffuse into the features becomes shorter, e.g. upon completion of operation 505 as shown in FIG. 5, switching to a lower copper and higher acid electroplating bath, e.g. the second electroplating bath used in operation 507, helps improve WIW and WID. Thus, by focusing on WID and WIW performance initially, then WIF later on during the electroplating process, WID and WIF can be improved beyond usage of either electroplating bath alone.

WID, WIW and WIF Types of Feature Non-Uniformity

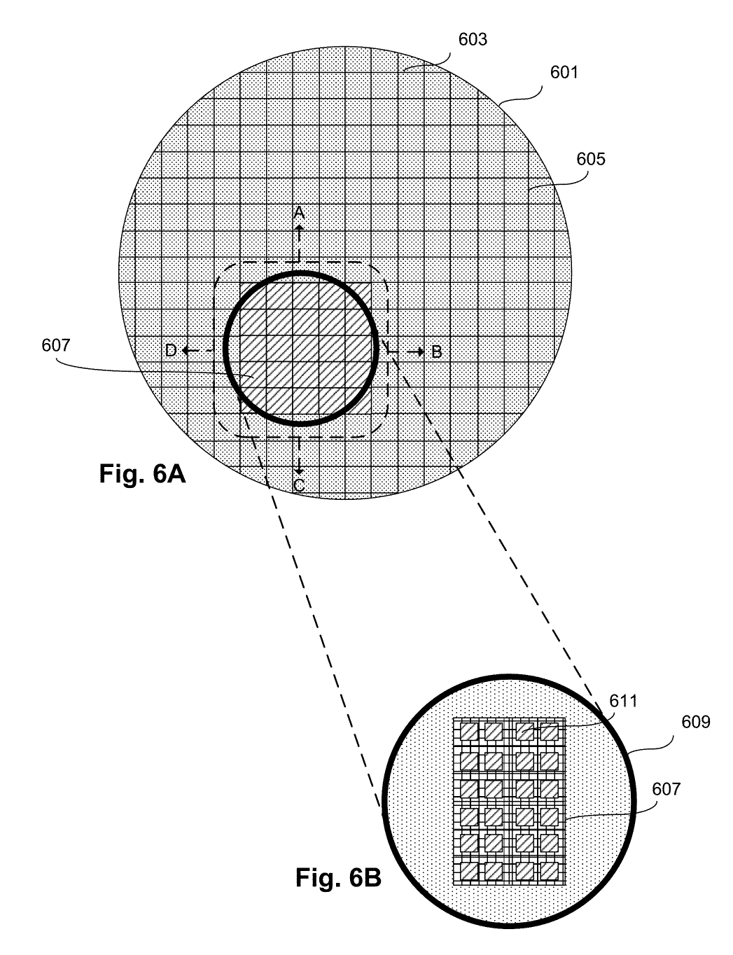

For context, FIGS. 6A and 6B show wafer 601 with an enlarged portion 609 thereof showing die 607 with features 611 formed therein. One skilled in the art will appreciate that FIGS. 6A and 6B are not to size and may have other shapes or orientations. Conventionally, wafer 601 is formed through methods or processes known in the art and may comprise substances with desirable physical properties, e.g. silicon. Manufacture of integrated circuits (ICs) on dies 607, which extend throughout wafer 601 in directions A-D as shown in FIG. 6A, involves slicing wafer 601 along horizontal and vertical lines 603 and 605, respectively, in a process referred to as “dicing” or separation, typically handled in a dedicated cutter tool. Dies 607, with features 611 formed therein as shown in enlarged section 609, are then packaged as needed.

In contrast to the conventional wafer manufacturing process described above of slicing the wafer into individual circuits (referred to as “dice”) and then packaging them, WLP involves packaging of an IC while it is still part of the wafer. Maintenance of tight uniformity regarding WID, WIW and WIF of pillars, e.g. formed of metal 113 as shown in FIG. 1D, is often highly desirable in WLP applications.

Details of WID, WIW, and WIF feature non-uniformity are shown in FIGS. 7A-7C. As described earlier, WID, WIW and WIF characterize non-uniformity of features, e.g. pillars formed from metal 113 as shown in FIG. 1D. Also, as described, the specific chemical compositions of metal and acid in an electroplating bath, and the relative concentrations thereof, influence feature non-uniformity. Namely, WID and WIW may be improved by high acid concentrations, and WIF may be improved by a high copper concentration.

WID may be calculated as shown in FIG. 7A. A first die and a second die, 707A and 707A′, respectively, are shown with a corresponding first and second set of pillars, 705A and 705A′, formed thereon. Variance in the height range of the pillars on each die, e.g. the first set of pillars 705A on first die 707A is measured. Line 711A is drawn across first die 707A at the apex of the lowest pillar 713A on die 707A. Similarly, line 709A is drawn across first die 707A at the apex of the highest pillar 715A on die 707A. Thus, first range 717A of pillar heights across first die 707A is measured as the distance from line 709A to line 711A. Similar to that discussed to calculate first range 717A, second range 717A′ may be calculated by measuring the distance from line 709A′ to line 711A′ on second die 707A′. Accordingly, variance between first range 717A and second range 717A (as well as subsequent ranges calculated in a similar manner as discussed for the first and second ranges across other dies on a given wafer) may be averaged over the entire wafer to determine WID. Thus, the average height variation per die may be evaluated across the entire wafer to determine WID.

Further, the methods provided herein can be used to improve within-wafer non-uniformity (WIW), as shown in FIG. 7B. In some embodiments, certain areas of a wafer, such as wafer 701B comprising dies 707B and 707B′ as shown in FIG. 7B, may experience thicker or thinner electroplating than desired. WIW non-uniformity may be measured by taking an average feature height for each die, e.g. as shown by line 713B for first die 707B and line 715B′ for second die 707B′, as measured on a single feature type in a die at multiple locations across the wafer's surface. The WIW non-uniformity is the maximum difference (range) between average feature height across all dies on the wafer, i.e., between the die with the highest average height and the die with the lowest average height.

FIG. 7C illustrates calculation of within-feature (WIF) non-uniformity. On a substrate having a plurality of pillars, such as a first and second pillar 705C and 705C′ formed on first die 707C, a range is calculated for each pillar as a height difference between the thickest part of the pillar and the thinnest part of the pillar (typically the height difference between the center of the pillar and the edge of the pillar). The average of these ranges (over all features of the wafer, or a representative sample thereof) is the WIF non-uniformity.

While these calculations are shown in FIG. 7C are as applied to the pillars after removal of a surrounding through-mask, it is understood that one can similarly calculate and/or estimate non-uniformity prior to mask removal. In some embodiments provided methods can be used to provide megapillar substrates with WIF of less than about 3%, WID of less than about 10%, WIW of less than about 4% and any combination thereof (values given as half-range percentage of feature height).

Exemplary Results

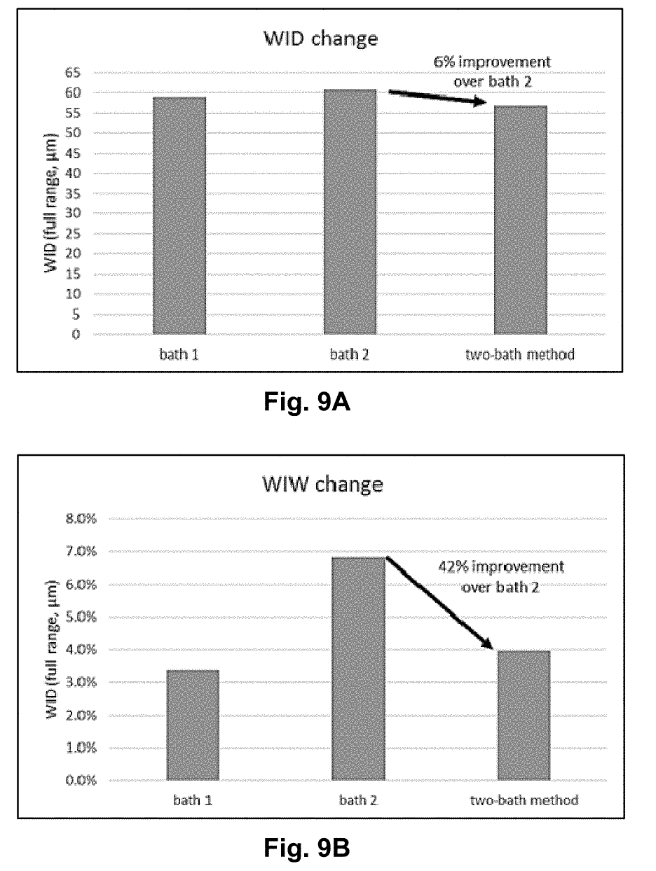

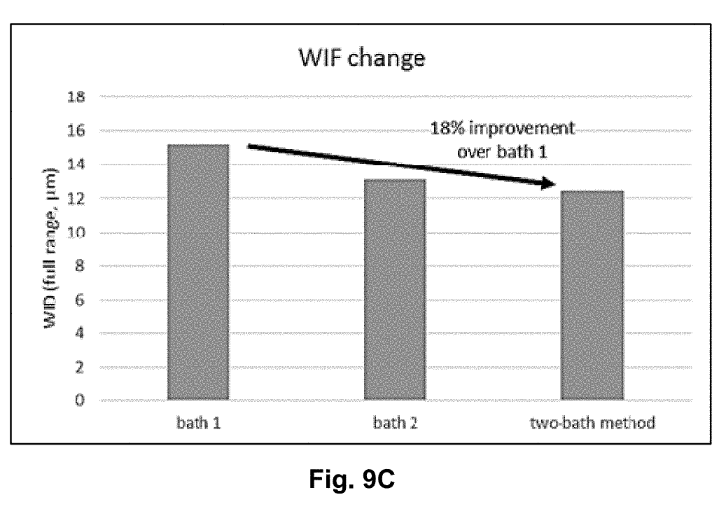

FIGS. 9A-9C show results of a multi-bath electroplating approach such as that presented with reference to FIGS. 2 and 5. As discussed earlier, the first electroplating bath, e.g. “bath 1” as shown in FIGS. 9A-9C, with a concentration of 85 g/l of copper provided by copper sulfate in 145 g/l of sulfuric acid with the Dow Intervia 9000 additive package provides good WID and WIW non-uniformity performance, as shown in FIGS. 9A and 9B. The second electroplating bath, e.g. “bath 2” as shown in FIGS. 9A-9C, with a concentration of 70 g/l of copper provided by copper sulfate in 190 g/l of sulfuric acid with the Enthone SC additive package, provides good WIF non-uniformity performance, as shown in FIG. 9C. However, neither bath, when used alone, shows good WID, WIW, and WIF non-uniformity performance. Substantial improvements are observed in WID, WIW, and WIF when two baths are used. For example, as shown in FIG. 9C, an 18% improvement in WIF is observed over usage of bath 1 alone. Accordingly, the multi-bath electroplating approach shows significant improvement in all metrics, e.g. WID, WID and WIF. For instance, both WID and WIW are significantly better than plating only in bath 2, and WIF is significantly better than plating only in bath 1.

Contextual Workflows

FIGS. 10A-10 C show various processes for conducting electroplating in accordance with embodiments of this disclosure. Process 1009A shown in FIG. 10A may resemble that traditionally used involving a single copper plating operation, at operation 1005A. The process begins at operation 1001A with a substrate or wafer undergoing processing exposed to a pre-wet conducted at operation 1003A. The pre-wet may be carried out in accordance with methods and apparatus associated with electroplating processes, such as those disclosed by U.S. Pat. No. 8,962,085 entitled “WETTING PRETREATMENT FOR ENHANCED DAMASCENE METAL FILLING,” U.S. Pat. No. 9,455,139 entitled “METHODS AND APPARATUS FOR WETTING PRETREATMENT FOR THROUGH RESIST METAL PLATING.” Next, the wafer is contacted with a single copper ion plating bath at operation 1005A, followed by a traditional “spin rinse dry” (SRD) at operation 1007A to conclude at operation 1011A. As discussed earlier, limitations of usage of the single-bath approach shown in FIG. 10A include difficulties in optimizing all three metrics of WID, WIW, and WIF, particularly at high electroplating rates.

FIG. 10B shows a variation of the single-bath electroplating process shown in FIG. 10A by adding an additional copper plating operation 1013B. Remaining process operations 1001B through 1011B correspond with like operations shown and discussed for FIG. 10A. That shown in FIG. 10B may have all plating operations, e.g. copper plating at operation 1005B and additional copper plating at 1013B, conducted on two duets on a single electroplating tool. A duet refers to a pair of electroplating chambers which share certain resources, such as a reservoir containing electroplating solution, or bath. Here, for process 1009B, the duets may contain, respectively, baths having different compositions as necessary to optimize WID, WIW, and WIF as discussed earlier. And, generally, each duet can be connected to one or more other duets as per process requirements. In certain embodiments, a tool used to conduct operation 1009B may include four, or eight duets, for a configuration including eight or sixteen electroplating chambers, respectively. Of course, duet architecture is not required for practice of the embodiments in FIG. 10B. The electroplating bath reservoirs for the various duets may be filled with a first electroplating bath having a first composition, with the remainder filled with a second electroplating bath having a second composition. As discussed earlier, each of the first and second electroplating baths may have varying concentrations of metal and acid to provide for optimal plating of a single metal across all three metrics of WID, WIW, and WIF.

Alternative to using one or more duets and introduced and discussed above, the multi-bath electroplating process shown in FIG. 10B may have all plating operations conducted sequentially in a single, e.g. shared, chamber. For instance, a first bath may be flowed into the chamber (not shown in FIG. 10B). A wafer intended for electroplating, after being pre-wetted at operation 1003B, may be immersed into the first bath in the chamber for electroplating. The wafer may then be removed from the bath in the chamber to allow for the first bath to be fully drained from the chamber. In certain embodiments, the chamber may be rinsed to remove any residue of the first bath therefrom, e.g. between plating copper plating operation 1005B and additional copper plating operation 1013B. Next, a second bath is flowed into the chamber, where the second bath has a different concentration of a shared common ion with the first bath, e.g. as described earlier in various embodiments. The wafer is then re-inserted into the second bath in the chamber for additional electroplating therefrom prior to ultimate removal of the wafer and progression to SRD conducted at operation 1007B prior to conclusion of the process at end 1011B.

As an alternative to that presented by process 1009B shown in FIG. 10B, electroplating by a multiple-bath approach may be expanded to conduct plating in electroplating chambers located on separate tools, as shown in FIG. 10C, with a complete process 1009C and 1009C′ conducted on a first and second tool, respectively. Processes shown in 1009C and 1009C′ are like that shown and discussed for process 1009A shown in FIG. 10A, except that additional copper plating conducted at operation 1005C′ is from a bath having a different composition than that used for operation 1005C, e.g. to achieve optimization across WID, WIW, and WIF.

Apparatus

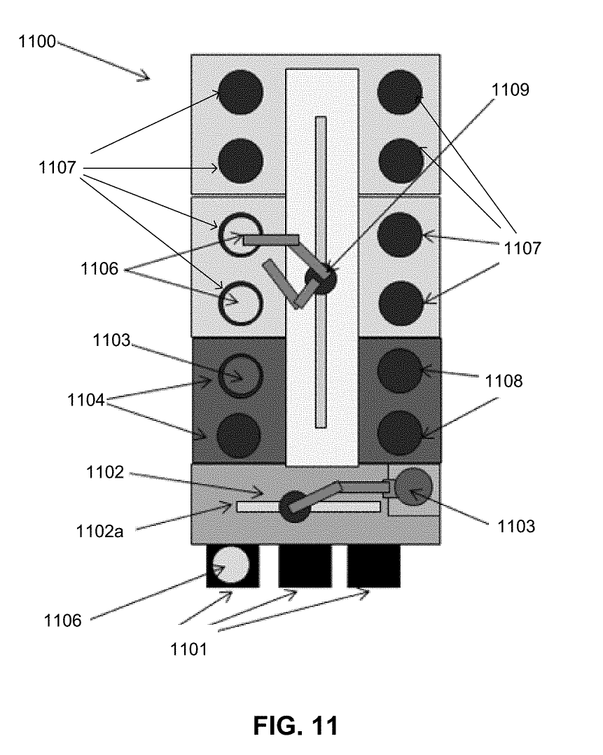

An embodiment of an electrodeposition apparatus 1100 is schematically illustrated in FIG. 11. In this embodiment, the electrodeposition apparatus 1100 has a set of electroplating cells 1107, each containing an electroplating bath, in a paired or multiple “duet” configuration. Electroplating cells 1107 may be configured to be filled with one or more electroplating baths, each bath filling a cell 1107 and having a chemical composition and/or concentration of metal ions distinct from the other remaining baths. Further, all of the baths may have concentrations of the same metal, such that electroplating cells 1107 may be used to deposit the same metal, e.g., copper. In addition to electroplating per se, the electrodeposition apparatus 1100 may perform a variety of other electroplating related processes and sub-steps, such as spin-rinsing, spin-drying, metal and silicon wet etching, electroless deposition, pre-wetting and pre-chemical treating, reducing, annealing, photoresist stripping, and surface pre-activation, for example. The electrodeposition apparatus 1100 is shown schematically looking top down in FIG. 11, and only a single level or “floor” is revealed in the figure, but it is to be readily understood by one having ordinary skill in the art that such an apparatus, e.g., the Sabre® 3D tool available from Lam Research of Fremont, Calif., can have two or more levels “stacked” on top of each other, each potentially having identical or different types of processing stations.

Referring again to FIG. 11, substrates 1106 that are to be electroplated are generally fed to the electrodeposition apparatus 1100 through a front end loading FOUP 1101 and, in this example, are brought from the FOUP to the main substrate processing area of the electrodeposition apparatus 1100 via a front-end robot 1102 that can retract and move a substrate 1106 driven by a spindle 1103 in multiple dimensions from one station to another of the accessible stations-two front-end accessible stations 1104 and also two front-end accessible stations 1108 are shown in this example. The front-end accessible stations 1104 and 1108 may include, for example, pre-treatment stations, and spin rinse drying (SRD) stations. Lateral movement from side-to-side of the front-end robot 1102 is accomplished utilizing robot track 1102a. Each of the substrates 1106 may be held by a cup/cone assembly (not shown) driven by a spindle 1103 connected to a motor (not shown), and the motor may be attached to a mounting bracket 1109. Also shown in this example are the four “duets” of electroplating cells 1107, for a total of eight electroplating cells 1107. A system controller (not shown) may be coupled to the electrodeposition apparatus 1100 to control some or all of the properties of the electrodeposition apparatus 1100. The system controller may be programmed or otherwise configured to execute instructions according to processes described earlier herein.

System Controller

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as a “system controller” or “controller,” and may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of electroplating a metal into features of a lithographic mask of a partially fabricated electronic device on a substrate, the method comprising:
(a) electroplating the metal into the features, to partially fill the features of the lithographic mask by a bottom up fill mechanism, while contacting the features with a first electroplating bath having a first composition and comprising ions of the metal;
(b) thereafter, electroplating more of the metal into the features, to further fill the features of the lithographic mask, while contacting the features with a second electroplating bath having a second composition, which is different than the first composition, and comprises the ions of the metal; and
(c) removing the substrate from an electroplating tool where operation (b) was performed.

2. The method of claim 1, wherein the metal is copper.

3. The method of claim 1, wherein the first electroplating bath and the second electroplating bath each comprise an acid.

4. The method of claim 3, wherein the first electroplating bath comprises only one type of dissolved anion.

5. The method of claim 1, wherein the first electroplating bath and the second electroplating bath each comprise copper sulfate and sulfuric acid.

6. The method of claim 1, wherein the first electroplating bath comprises two dissolved anions.

7. The method of claim 1, wherein the first electroplating bath comprises copper sulfate and methane sulfonic acid.

8. The method of claim 7, wherein the second electroplating bath comprises copper sulfate and sulfuric acid, but does not contain methane sulfonic acid.

9. The method of claim 1, wherein the first electroplating bath has a first concentration of the ions of the metal and the second electroplating bath has a second concentration of ions of the metal, and further wherein the first concentration of the ions of the metal is greater than the second concentration of the ions of the metal.

10. The method of claim 1, wherein the first electroplating bath has a first concentration of the ions of the metal and the second electroplating bath has a second concentration of ions of the metal, and further wherein the first concentration of the ions of the metal is less than the second concentration of the ions of the metal.

11. The method of claim 9, wherein the metal is copper and the first concentration of ions of the metal is between about 24 g/L and 90 g/L, and wherein the second concentration of ions of the metal is between about 24 g/L and 90 g/L.

12. The method of claim 1, wherein the first electroplating bath has a first concentration of acid and the second electroplating bath has a second concentration of acid, and wherein the second concentration of acid is greater than the first concentration of acid.

13. The method of claim 1, wherein the first electroplating bath has a first concentration of acid and the second electroplating bath has a second concentration of acid, and wherein the second concentration of acid is less than the first concentration of acid.

14. The method of claim 12, wherein the metal is copper and the first concentration of acid has a pH of between about −0.34 and 0.26, and wherein the second concentration of acid has a pH of between about −0.34 and 0.26.

15. The method of claim 1, wherein the first electroplating bath has a first additive composition and the second electroplating bath has a second additive composition, which is different from the first additive composition.

16. The method of claim 15, wherein, compared to the second additive composition, the first additive composition has stronger bottom-up fill properties.

17. The method of claim 15, wherein the first additive composition comprises a suppressor and an accelerator.

18. The method of claim 15, wherein, compared to the first additive composition, the second additive composition has stronger leveling properties.

19. The method of claim 1, wherein the electroplating in (a) is performed at a first temperature, and wherein the electroplating in (b) is performed at a second temperature that is lower than the first temperature.

20. The method of claim 1, wherein the electroplating in (a) is performed at a first current density that is below a first limiting current density for electroplating metal in the features during (a), and wherein the electroplating in (b) is performed at a second current density that is higher than first limiting current density, but lower than a second limiting current density for electroplating metal in the features during (b).

21. The method of claim 1, further comprising, after (b), electroplating even more of the metal into the features, while contacting the features with a third electroplating bath having a third composition, which is different than the second composition, and comprises the ions of the metal.

22. The method of claim 1, wherein operation (a) is performed in a first electroplating chamber and operation (b) is performed in a second electroplating chamber.

23. The method claim 22, wherein the first electroplating chamber is in a first electroplating tool having one or more stations and/or mechanisms shared by multiple electroplating chambers, including the first electroplating chamber, in the first electroplating tool, and wherein the second electroplating chamber is in a second electroplating tool that does not share the one or more stations and/or mechanisms of the first electroplating tool.

24. The method of claim 1, wherein operation (a) and operation (b) are performed in a single electroplating chamber, and wherein the first and second electroplating baths are flowed sequentially, first for operation (a) and then for operation (b), into the single electroplating chamber.

25. The method of claim 1, wherein the lithographic mask is a layer of photoresist on the substrate, and wherein electroplating the metal in operations (a) and (b) forms metal pillars in the holes.

26. The method of claim 1, wherein the metal pillars are a component of wafer level packaging.

27. The method of claim 26, further comprising forming a contact between the metal pillars and a tin silver composition.

28. The method of claim 1, wherein the features are holes or trenches having diameters or widths of at least about 150 micrometers.

29. The method of claim 1, wherein the features are holes or trenches having diameters or widths of at least about 200 micrometers.

30. The method of claim 1, wherein at least some of the features have an aspect ratio of between about 1:2 and 15:1.

31. The method of claim 1, wherein at least some of the features have aspect ratios of at least about 3:1.

32. A method of electroplating a metal into features of a partially fabricated electronic device on a substrate, the method comprising:
(a) electroplating the metal into the features, to partially fill the features while contacting the features with a first electroplating bath having a first composition comprising (i) acid having a first concentration of the acid and (ii) ions of the metal having a first concentration of ions of the metal;
(b) thereafter, electroplating more of the metal into the features, to further fill the features, while contacting the features with a second electroplating bath having a second composition, which is different than the first composition, and comprises (i) the acid having a second concentration of the acid, and (ii) the ions of the metal having a second concentration of ions of the metal, wherein the first concentration of the ions of the metal is greater than the second concentration of the ions of the metal, and wherein the second concentration of acid is greater than the first concentration of acid; and
(c) removing the substrate from an electroplating tool where operation (b) was performed.

33. The method of claim 32, wherein the features are holes in a lithographic mask on the substrate, and wherein electroplating the metal in operations (a) and (b) forms metal pillars in the holes.
